(19) United States
(12) Patent Application Publication
(10) Pub. No.: US 2010/0003119 A1
(43) Pub. Date: Jan. 7, 2010

(54) METHOD FOR PICKING UP DEVICE ATTACHED WITH ADHESIVE TAPE

(75) Inventor: Masaru Nakamura, Ota-Ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/168,437

(22) Filed: Jul. 7, 2008

(51) Int. Cl. H01L 21/00

(52) U.S. Cl. 414/800

(57) ABSTRACT

A method for picking up a device stuck with an adhesive film includes an tape expansion step for expanding a dicing tape to increase intervals between devices and between adhesive films by pressing an area between an inner diameter of the annular frame of the dicing tape and the wafer by means of an expansion member with the annular frame held; and a picking-up step for picking up the device and the adhesive film from the dicing tape. A relative shifting rate between the expansion member and the frame holding means is set to 100 mm/second or more when the expansion member and the dicing tape are brought into abutment against each other in the tape expansion step, and the increased intervals between the devices and between the adhesive films are each set to 100 μm or more.

### BACKGROUND OF THE INVENTION

1. Field of the Invention

The present invention relates to a device picking-up method for picking up devices resulting from dividing a wafer along a plurality of streets, the wafer being formed on a front surface with the streets in a lattice pattern and stuck to a dicing tape, the devices being formed in a plurality of areas sectioned by the streets.

2. Description of the Related Art

For example, in a semiconductor device fabrication step, devices such as ICs, LSIs or the like are formed in a plurality of areas sectioned by streets (predetermined cutting lines) formed in a lattice pattern on the front surface of an approximately disklike semiconductor wafer. In addition, the areas formed with the devices therein are divided along the streets to fabricate individual semiconductor chips. A cutting device generally called a dicing machine is used as a dividing device for dividing a semiconductor wafer. This cutting device uses a cutting blade with a thickness of about 20 μm to cut the semiconductor wafer along the streets. The semiconductor chips divided as described above are each packaged and widely used in electrical equipment such as a mobile phone, a personal computer, etc.

A die-bonding adhesive film made of an epoxy resin or the like and called a die attach film with a thickness of about 20 to 40 μm is attached to the rear surface of the individually divided semiconductor chips. The semiconductor chips are thermal-compression bonded to a die bonding frame supporting the semiconductor chips via the adhesive film. A method of attaching the die-bonding adhesive film to the rear surface of a semiconductor chip involves sticking the adhesive film to the rear surface of the semiconductor wafer, sticking the semiconductor wafer to the dicing tape via the adhesive tape, and then cutting the semiconductor wafer together with the adhesive film along the streets formed on the front surface of the semiconductor wafer by a cutting blade, thereby forming semiconductor chips attached with the adhesive tape on the rear surface thereof (see e.g. Japanese Patent Laid-Open No. 2000-182995).

In recent years, electrical equipment such as mobile phones, personal computers, and the like is required to have reduced weight and small size, that is, thinner semiconductor chips are required. A dividing technique so-called “dicing before grinding” is put to practical use as a technique for dividing thinner semiconductor chips. This dicing before grinding is a technique as below. Division grooves are formed in the front surface of a semiconductor wafer along streets to have a predetermined depth (the depth corresponding to a finishing thickness of a semiconductor chip). Then the rear surface of the semiconductor wafer is ground at portions corresponding to the division grooves formed in the front surface thereof to expose the division grooves to the rear surface. Thus, the semiconductor wafer is divided into individual semiconductor chips. This technique can process a semiconductor wafer into semiconductor chips with a thickness of 50 μm or less.

In the case of dividing the semiconductor wafer into the individual semiconductor chips by dicing before grinding, after the dividing grooves with a predetermined depth are formed in the front surface of the semiconductor wafer along the streets, the rear surface of the semiconductor wafer is ground to expose the dividing grooves to the rear surface. It is not possible to previously attach the die-bonding adhesive film on the rear surface of the semiconductor wafer. Thus, when the semiconductor chips divided by the dicing before grinding are bonded to the die bonding frame, such bonding have to be done while bond is being inserted between the semiconductor chips and the die bonding frame. This poses a problem in that bonding work cannot be executed smoothly.

To eliminate such a problem, a semiconductor chip fabrication method as below is proposed. In this method, a die-bonding adhesive film is stuck to the rear surface of a semiconductor wafer divided into individual semiconductor chips by dicing before grinding. The semiconductor wafer is stuck to the dicing tape via the adhesive film. Thereafter, a laser beam is applied via a gap defined between the semiconductor chips to a portion of the adhesive film exposed to the gap from the front surface side of the semiconductor chip to remove the portion of the adhesive film exposed to the gap. See e.g. Japanese Patent Laid-Open No. 2002-118081.

In this way, the adhesive film is cut by a cutting blade or a laser beam along devices divided along the streets. In this case, the outer circumferential portion of the adhesive film is tangled with and adheres to the adhesive glue of the dicing tape. When the device is picked up from the dicing tape, beard-like dust occurs and adheres to the adhesive film attached to the rear surface of the device, which causes poor die bonding or poor wiring.

### SUMMARY OF THE INVENTION

Accordingly, it is an object of the present invention to provide a device picking-up method in which even if beard-like dust occurs at the time of picking up a device from a dicing tape, the beard-like dust is left on the dicing tape so that it does not adhere to the adhesive film attached to the rear surface of the device.

In accordance with an aspect of the present invention, there is provided a method for picking up a device stuck with an adhesive film from a dicing tape, a rear surface of a wafer being stuck via the adhesive film to the dicing tape attached to an annular frame, the wafer being formed on a front surface with a plurality of streets in a lattice pattern, devices being formed in a plurality of areas sectioned by the streets, the wafer and the adhesive film being each divided along streets for each of the devices, the method including an tape expansion step for expanding the dicing tape to increase intervals between the devices and between the adhesive films by pressing an area between an inner diameter of the annular frame of the dicing tape and the wafer by means of an expansion member with the annular frame held by a frame holding means; and a picking-up step for picking up the device and the adhesive film from the dicing tape with the intervals between the devices and between the adhesive films stuck to the dicing tape increased by the tape expansion step.

A relative shifting rate between the expansion member and the frame holding means is set to 100 mm/second or more when the expansion member and the dicing tape are brought into abutment against each other in the tape expansion step, and the increased intervals between the devices and between the adhesive films are each set to 100 μm or more.

Preferably, the adhesive film is cooled to 10° C. or lower in the tape expansion step.

According to the present invention, in the tape expansion step, the relative shifting rate between the expansion member and the frame holding means is set to 100 mm/second or more when the expansion member and the dicing tape are brought into abutment against each other, and the intervals between the devices and between the adhesive films are each set to 100 μm or more. Therefore, although beard-like dust occurs when the device is picked up from the dicing tape, it is left on the dicing taper that is, it does not adhere to the adhesive film.

The above and other object, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a state where a semiconductor wafer attached with a die-bonding adhesive film on the rear surface is stuck to a dicing tape attached to an annular frame;

FIG. 2 is a perspective view illustrating a state where the semiconductor wafer and adhesive film shown in FIG. 1 are each divided for each device;

FIG. 3 is a perspective view of a picking-up device for executing a method for picking up a device attached with the adhesive film according to the present invention;

FIG. 4 is a perspective view illustrating an essential portion of the picking-up device shown in FIG. 3;

FIG. 5 is a cross-sectional view illustrating a second table, frame holding means and tape expansion means constituting the picking-up device shown in FIG. 3;

FIGS. 6A, 6B and 6C are explanatory views illustrating a tape expansion step in the method for picking up a device attached with the adhesive film according to the present invention; and

FIG. 7 is an explanatory view illustrating a picking-up step in the method for picking up a device attached with the adhesive film according to the present invention.

### DETAILED DESCRIPTION OF THE PREFERRED EMBODIMENTS

A method for picking up a device stuck with a adhesive film according to preferred embodiments of the present invention will hereinafter be described in detail with reference to the accompanying drawings. In this case, a description is given of a wafer stuck with a adhesive film on a rear surface.

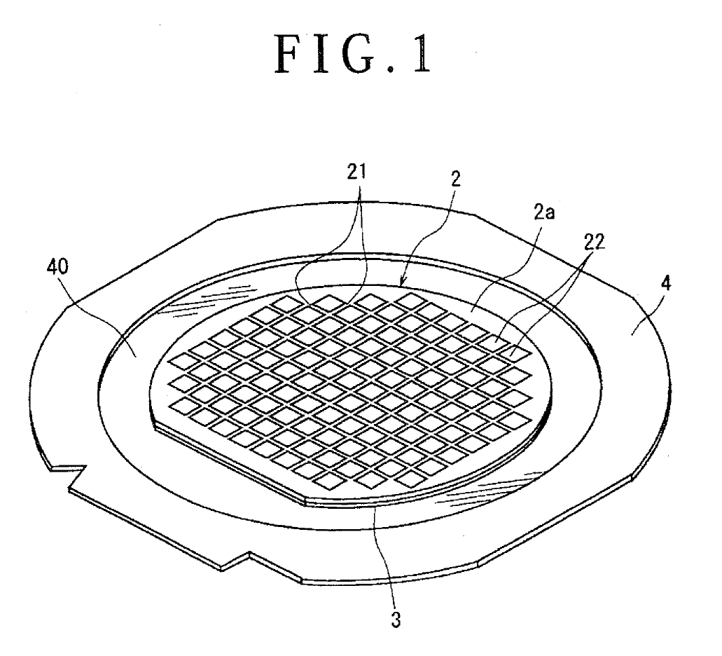

FIG. 1 illustrates a state where a die-bonding adhesive film 3 is attached to the rear surface of a semiconductor wafer 2 and the semiconductor wafer 2 is stuck via the adhesive film 3 to a dicing tape 40 attached to an annular frame 4. The semiconductor wafer 2 shown in FIG. 1 is formed on a front surface 2a with a plurality of streets 21 in a lattice pattern and devices 22 are formed in a plurality of areas sectioned by the streets 21. The adhesive film 3 includes an epoxy resin film with a thickness of 20 to 40 μm. In addition, the adhesive film 3 is pressed against and attached to the rear surface of the semiconductor wafer 2 while being heated at a temperature of 80 to 200° C. The annular frame 4 is made of stainless steel with a thickness of 1 mm. In the illustrated embodiment, the dicing tape 40 is formed such that acryl resin based glue is applied to about 5 μm on the front surface of a sheet base made of polyvinyl chloride to have a thickness of 70 μm.

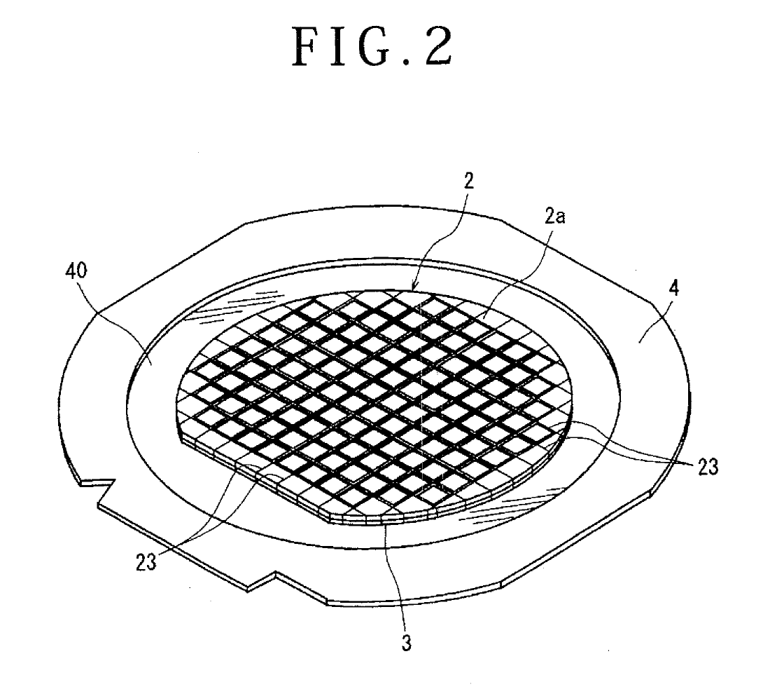

The semiconductor wafer 2 stuck to the front surface of the dicing tape 40 attached to the annular frame 4 as described above is cut along the streets 21 by a cutting device provided with a cutting blade and divided into the individual devices 22 as shown in FIG. 2. In this case, also the die-bonding adhesive film 3 attached to the rear surface of the semiconductor wafer 2 is cut at the same time.

In the case of dividing the semiconductor wafer 2 into the individual devices by the so-called “dicing before grinding”, dividing grooves each having a predetermined depth (a depth corresponding to the finishing thickness of each semiconductor chip) are formed by use of the cutting device to extend along the streets 21 formed in the front surface 2a of the semiconductor wafer 2 (dividing groove forming step). Next, a protection member is attached to the front surface of the semiconductor wafer 2 formed with the dividing grooves and the rear surface of the semiconductor wafer 2 is ground to expose the dividing grooves to the rear surface, thereby dividing the semiconductor wafer 2 into the individual devices 22 (dividing groove exposing step). The die-bonding adhesive film 3 is attached to the rear surface of the semiconductor wafer 2 divided into the individual devices 22 as described above.

The adhesive film 3 attached to the rear surface of the semiconductor wafer 2 (and divided into pieces corresponding to the individual devices 22) is stuck to the front surface of the dicing tape 40 attached to the annular frame 4 mentioned above. In this state, a laser beam is applied to and cuts the adhesive film 3 along the dividing grooves. Thus, the individual devices resulting from the semiconductor wafer 2 divided along the streets 21 and the adhesive film 3 cut along the dividing grooves are brought into a state where they are stuck to the front surface of the dicing tape 40 attached to the annular frame 4 as shown in FIG. 2.

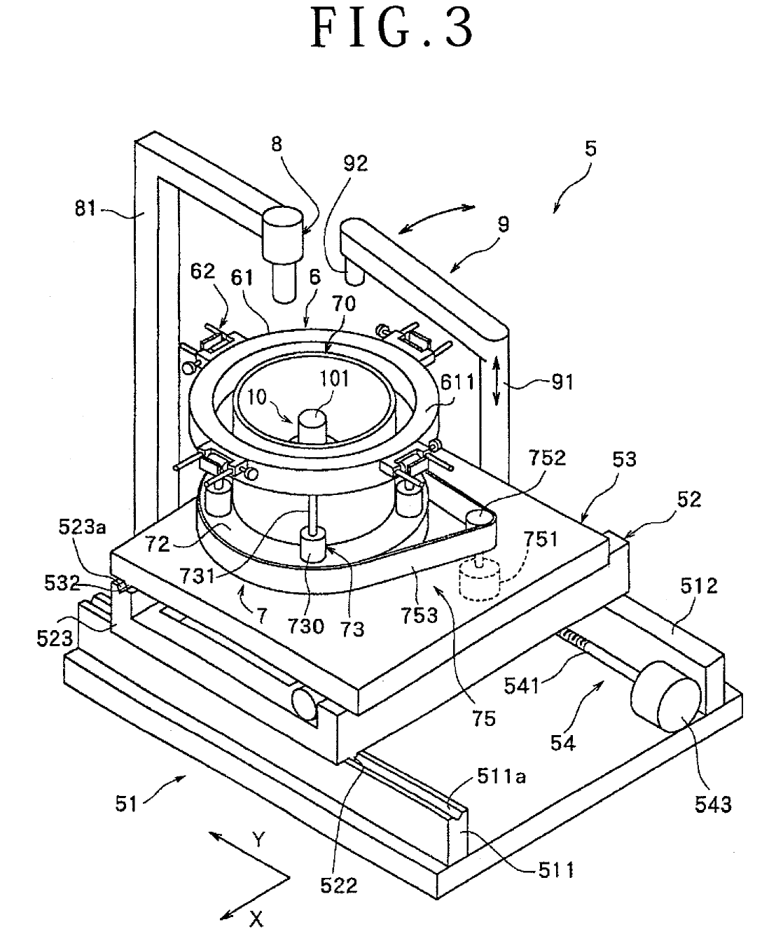

The individual devices 22 stuck to the front surface of the dicing tape 40 via the adhesive film 3 as described above are conveyed to a picking-up device and picked up from the dicing tape 40. The picking-up device is here described with reference to FIGS. 3, 4 and 5 by way of example.

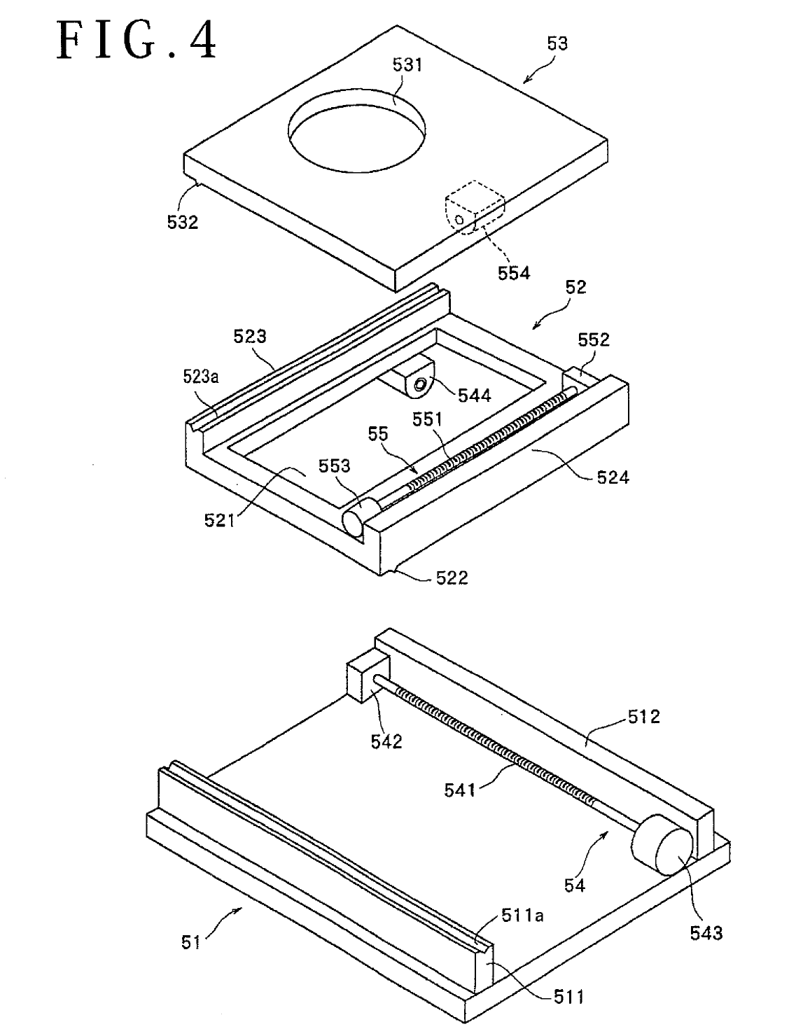

FIG. 3 is a perspective view of the picking-up device and FIG. 4 is an exploded perspective view illustrating an essential portion of the picking-up device shown in FIG. 3. The picking-up device 5 includes a base 51; a first table 52 disposed on the base 51 to be shiftable in the direction indicated with arrow Y; and a second table 53 disposed on the first table 52 to be shiftable in the direction, indicated with arrow X, perpendicular to the direction indicated with the arrow Y. The base 51 is formed like a rectangle and two guide rails 511, 512 are disposed parallel to each other on the upper surfaces of the side portions to extend in the direction indicated with arrow Y. Incidentally, a first guide rail 511 of the two guide rails is formed with a guide groove 511a V-shaped in cross-section on the upper surface thereof.

The first table 52 is formed like a window frame provided with a rectangular opening 521 at a central portion as shown in FIG. 4. The first table 52 is provided at one lateral lower surface with a to-be-guided rail 522 slidably fitted to the guide groove 511a formed in the first guide rail 511 provided on the base 51. Two guide rails 523, 524 are disposed parallel to each other on the lateral upper surface of the first table 52 so as to extend in the direction perpendicular to the to-be-guided rail 522. Incidentally, a first guide rail 523 of the two guide rails 523, 524 is formed with a guide groove 523 V-shaped in cross-section on the upper surface thereof. The first table 52 configured as above is such that the to-be-guided rail 522 is fitted to the guide groove 511a formed in the first guide rail 511 provided on the base 51 and the other lateral lower surface is put on the second guide rail 512 provided on the base 51.

The picking-up device 5 is provided with first shifting means 54 for shifting the first table 52 in the direction indicated with arrow Y along the guide rails 511, 512 provided on the base 51. The first shifting means 54 includes, as shown in FIG. 4, an external screw rod 541 disposed parallel to the second guide rail 512 provided on the base 51; a bearing 542 adapted to turnably support one end of the external screw rod 541 disposed on the base 51; a pulse motor 543 for drivingly turning the external screw rod 541 connected to the other end of the external screw rod 541; and an external screw block 544 threadedly engaged with the external screw rod 541 provided on the lower surface of the first table 52. The first shifting means 54 constructed as above shifts the first table 52 in the direction indicated with arrow Y by driving the pulse motor 543 to turn the external screw rod 541.

The second table 53 is formed like a rectangle as shown in FIG. 4 and provided with a circular hole 531 at a central portion. The second table 53 is provided on the lower surface of one of lateral portions with a to-be-guided rail 532 slidably fitted to a guide groove 523a formed in the first guide rail 523 provided on the first table 52. The second table 53 constructed as above is such that the to-be-guided rail 532 is fitted to the guide groove 523a formed on the first guide rail 523 provided on the first table 52 as shown in FIG. 3 and the lower surface of the other lateral portion is put on the second guide rail 524 provided on the first table 52. The picking-up device 5 is provided with second shifting means 55 for shifting the second table 53 in the direction indicated with arrow X along the guide rails 523, 524 provided on the first table 52.

The second shifting means 55 includes, as shown in FIG. 4, an external screw rod 551 disposed parallel to the second guide rail 524 provided on the first table 52; a bearing 552 disposed on the first table 52 to turnably support one end of the external screw rod 551; a pulse motor 553 connected to the other end of the external screw rod 551 to drivingly turn the external screw rod 551; and an internal screw block 554 provided on the lower surface of the second table 53 and threadedly engaged with the external screw rod 551. The second shifting means 55 constructed as above shifts the second table 53 in the direction indicated with arrow X by driving the pulse motor 553 to turn the external screw rod 551.

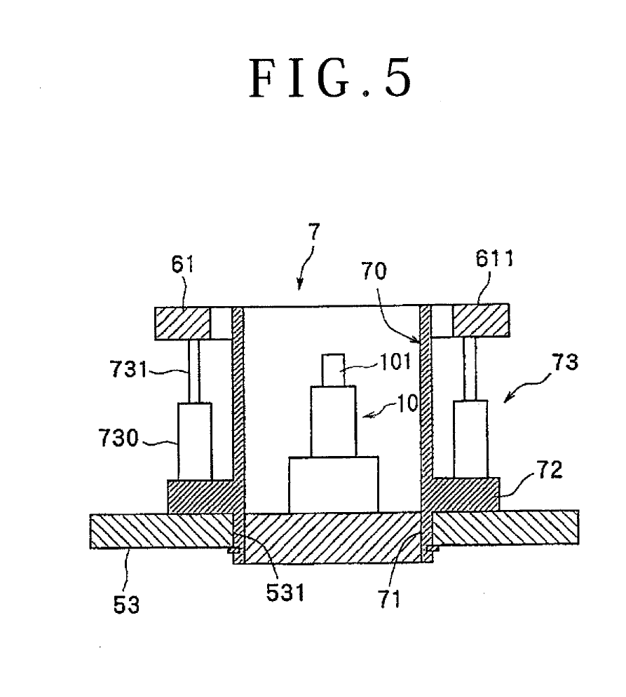

The picking-up device 5 includes frame holding means 6 for holding the annular frame 4 and tape expansion means 7 for expanding the dicing tape 40 attached to the annular frame 4 held by the frame holding means 6. The frame holding means 6 includes, as shown in FIGS. 3 and 5, an annular frame holding member 61 having an inner diameter greater than the diameter of the hole 531 provided in the second table 53; and a plurality of clamps 62 serving as securing means disposed at the outer circumference of the frame holding member 61. The frame holding member 61 is formed on an upper surface with a placing-surface 611 adapted to receive the annular frame 4 placed thereon. The annular frame 4 placed on the placing surface 611 is secured to the frame holding member 61 by the clamps 62. The frame holding means 6 constructed as above is disposed above the hole 531 of the second table 53 and supported by the tape expanding means 7 described later to be movable upward and downward.

The tape expansion means 7 includes an expansion drum 70 disposed inside the annular frame holding member 61 as shown in FIGS. 3 and 5. This expansion drum 70 has inner and outer diameters smaller than the inner diameter of the annular frame 4 and greater than the outer diameter of the semiconductor wafer 2 stuck to the dicing tape 40 attached to the annular frame 4. The expansion drum 70 is provided at a lower end with an attachment portion 71 turnably fitted to the inner circumferential surface of the hole 531 provided in the second table 53. In addition, the expansion drum 70 is provided at an upper outer circumferential surface of the attachment portion 71 with a support flange 72 formed to protrude in the radial direction. The tape expansion means 7 includes support means 73 capable of moving the annular frame holding member 61 upward and downward.

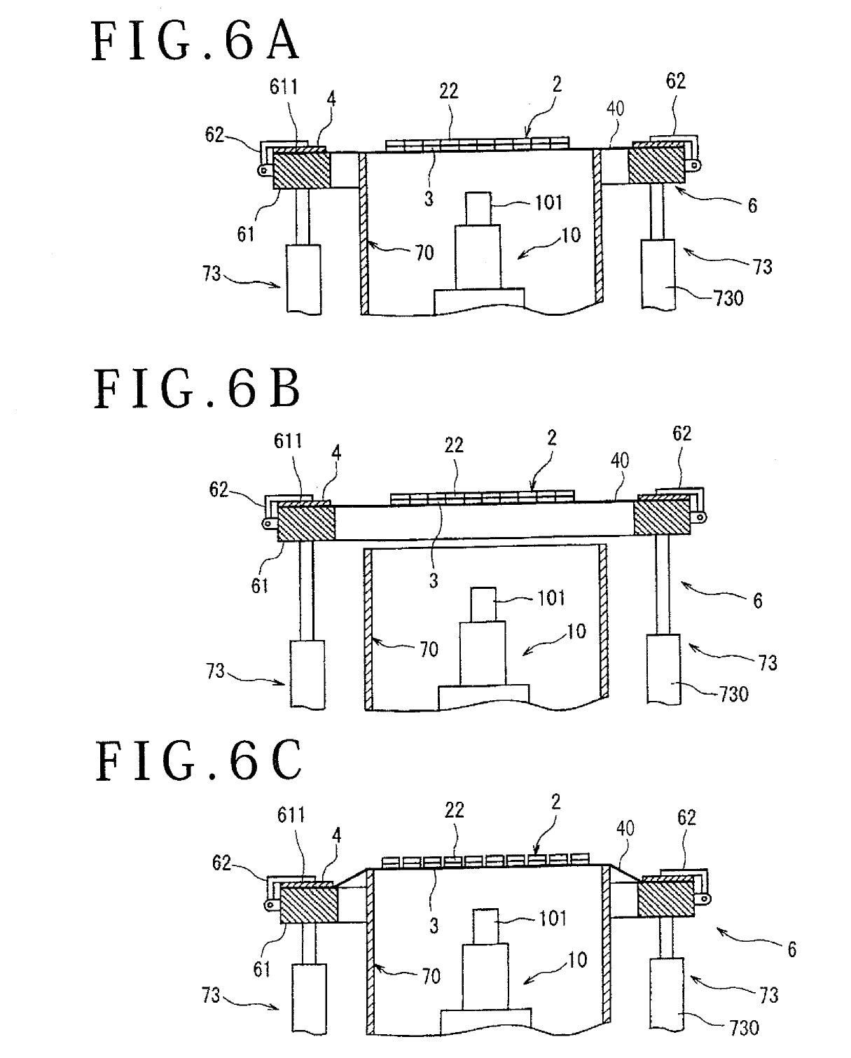

The holding means 73 is composed of a plurality of air cylinders 730 disposed on the support flange 72. Piston rods 731 of the air cylinders 730 are connected to the lower surface of the annular frame holding means 61. The support means 73 composed of the air cylinders 730 as mentioned above selectively shifts the frame holding member 61 to a reference position as shown in FIGS. 5 and 6A, to a separate position as shown in FIG. 6B and to an expansion position as shown in FIG. 6C. The reference position is such that the placing-surface 611 is located at a height approximately equal to that of the upper end of the expansion drum 70. The separate position is such that the placing-surface 611 is located at a position upwardly spaced by a predetermined distance from the upper end of the expansion drum 70 as shown in the figure. The expansion position is such that the placing-surface 611 is located at a position downwardly spaced by a predetermined distance from the upper end of the expansion drum 70 as shown in the figure. Thus, the support means 73 composed of the air cylinders 730 functions as expansion-shifting means for relatively shifting the expansion drum 70 and the frame holding member 61 upwardly and downwardly (in the axial direction).

The picking-up device 5 is provided with turning means 75 for turning the expansion drum 70 and the frame holding member 61 as shown in FIG. 3. This turning means 75 includes a pulse motor 751 disposed on the second table 53; a pulley 752 attached to the rotational shaft of the pulse motor 751; and an endless belt 753 wound around the pulley 752 and around the support flange 72 of the expansion drum 70. The turning means 75 constructed as above drives the pulse motor 751 to turn the expansion drum 70 via the pulley 752 and via the endless belt 753.

The picking-up device 5 is provided with detection means 8 for detecting the individually divided devices 22 of the semiconductor wafer 2 supported via the dicing tape 40 by the annular frame 4 held by the annular frame holding member 61. The detection means 8 is attached to an L-shaped support column 81 disposed on the base 51. The detection means 8 is composed of an optical system, an image pickup device (CCD) and the like. The detection means 8 picks up the images of the individually divided devices 22 of the semiconductor wafer 10 held via the dicing tape 40 by the annular frame 4 held by the annular frame holding member 61, converting them into electric signals, and sends the electric signals to control means not shown.

The picking-up device 5 is further provided with picking-up means 9 for picking up the individually divided devices 22 from the dicing tape 40. The picking-up means 9 includes a pivotal arm 91 disposed on the base 51 and a picking-up collet 92 attached to the leading end of the pivotal arm 91. The pivotal arm 91 is turned by the driving means not shown. The pivotal arm 91 is composed so as to be movable upward and down ward. The picking-up collet 92 attached to the leading end can pick up the individually divided devices 22 stuck to the dicing tape 40.

Referring again to FIG. 5, the picking-up device 5 is provided with cooling means 10 disposed in the expansion drum 70 constituting part of the tape expansion means 7. The cooling means 10 includes a cooling fluid spray nozzle 101 facing the upside and communicating with cooling fluid supply means not shown.

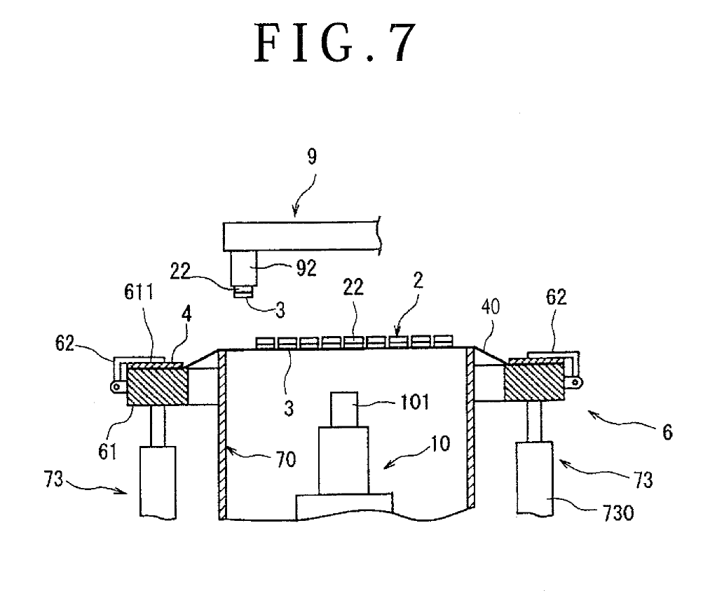

The picking-up device 5 is constructed as above. A description is given of a procedure for picking up from the dicing tape 40 the individual devices 22 stuck via the adhesive film 3 to the front surface of the dicing tape 40 mentioned above with, mainly, reference to FIGS. 6A to 6C and 7.

The annular frame 4 supports via the dicing tape 40 the individual devices 22 attached with the adhesive film 3 on the rear surface as shown in FIG. 2. In addition, the annular frame 4 is placed on the placing-surface 611 of the frame holding member 61 constituting part of the frame holding means 6 as shown in FIG. 6A and is secured to the frame holding member 61 by means of the clamps 62 (the frame holding step). In this case, the frame holding member 61 is located at the reference position shown in FIG. 6A.

The annular frame 4 supporting via the dicing tape 40 the individual devices 22 attached with the adhesive film 3 on the rear surface is secured to the frame holding member 61 located at the reference position as shown in FIG. 6A. Thereafter, the air cylinders 730 serving as the support means 73 constituting part of the tape expansion means 7 is actuated to lift the annular frame holding member 61 to the separate position shown in FIG. 6B (the separate position positioning step).

Next, the air cylinders 730 serving as the support means 73 constituting part of the tape expansion means 7 is actuated to lower the annular frame support member 61 to the expansion position shown in FIG. 6C at one stroke. Thus, since also the annular frame 4 secured to the placing-surface 611 of the frame holding member 61 is lowered, the dicing tape 40 attached to the annular frame 4 as shown in FIG. 6C is brought into abutment against the upper edge of the expansion drum 70 for expansion (the tape expansion step). In this case, since the dicing tape 40 attached to the annular frame holding member 61, i.e., to the annular frame 4 is lowered from the separate position shown in FIG. 6B, it reaches a predetermined shifting rate when coming into abutment against the upper edge of the expansion drum 70. Incidentally, it is important that the predetermined shifting rate is 100 mm/second or more when the dicing tape 40 comes into abutment against the upper edge of the expansion drum 70.

Consequently, a tensile force is radially and suddenly applied to the adhesive film 3 stuck to the rear surface of the individual devices 22 stuck to the dicing tape 40 to suddenly increase the intervals between the individually divided devices 22 and between the adhesive films 3. It is important that the intervals between the individually divided devices 22 and between the adhesive films 3 are each set to 100 μm or more. If the semiconductor wafer 2 is cut along the streets by the cutting blade with a width of 20 μm, the intervals between the devices 22 and between the adhesive films 3 are each increased to 120 μm or more in the tape expansion step. Incidentally, when the tape expansion step is executed, it is desirable that, if the placing-surface is located at the reference position as shown in FIG. 6A, the cooling means 10 be actuated to spray cooling fluid from the cooling fluid spray nozzle 101 for cooling the adhesive film 3 to 10° C. or lower.

After the execution of the tape expansion step as described above, the first and second shifting means 54, 55 are actuated to shift the first table 52 in the direction indicated with arrow Y (see FIG. 3) and to shift the second table 53 in the direction indicated with arrow X (see FIG. 3). Thus, the individual devices 22 stuck to the dicing tape 40 attached to the annular frame 4 held by the frame holding member 61 are each positioned immediately below the detection means 8. Then, the detection means 8 is actuated to check whether or not a gap between the individual devices 22 is aligned with the direction indicated with arrow X or Y. If the gap deviates from the direction indicated with arrow X or Y, the turning means 75 is actuated to turn the frame holding means 6 to allow the gap to be aligned with the direction indicated with arrow X or Y. Next, while the first table 52 is shifted in the direction indicated with arrow Y (see FIG. 3) and the second table 53 is shifted in the direction indicated with arrow X (see FIG. 3), the picking-up means 9 is actuated to allow the picking-up collet 92 to pick up a device 22 positioned at a predetermined position (the picking-up step). Then the device 22 picked up is conveyed to a tray not shown or to a die-bonding step.

In the picking-up step, the device 22 is separated from the dicing tape 40 and picked up with the adhesive film 3 attached to the rear surface of the device 22. At this time, the outer circumferential portion of the adhesive film 3 is tangled with and adheres to the adhesive glue of the dicing tape 40. When the device 22 is picked up from the dicing tape 40, beard-like dust occurs. When the intervals between the individually divided devices 22 and between the adhesive films 3 are increased in the tape expansion step, the shifting rate is 100 mm/second or more and each of the increased intervals between the devices 22 and between the adhesive films 3 is 100 μm or more. Thus, the beard-like dust will not be left on the side of the dicing tape 40 so that it does not adhere to the adhesive film 3. The experiment by the inventor revealed that the lower than 100 mm/second the shifting rate is, the higher the rate of the beard-like dust adhering to the adhesive film 3 is, and that the smaller than 100 μm the increased intervals between the devices and between the adhesive films 3 are, the higher the rate of the beard-like dust adhering to the adhesive film 3 is. In addition, cooling the adhesive film 3 to 10° C. or lower in the tape expansion step further reduces the rate of the beard-like dust adhering to the adhesive film 3 during the picking-up.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method for picking up a device stuck with an adhesive film from a dicing tape, a rear surface of a wafer being stuck via the adhesive film to the dicing tape attached to an annular frame, the wafer being formed on a front surface with a plurality of streets in a lattice pattern, devices being formed in a plurality of areas sectioned by the streets, the wafer and the adhesive film being each divided along streets for each of the devices, the method comprising:
an tape expansion step for expanding the dicing tape to increase intervals between the devices and between the adhesive films by pressing an area between an inner diameter of the annular frame of the dicing tape and the wafer by means of an expansion member with the annular frame held by a frame holding means; and
a picking-up step for picking up the device and the adhesive film from the dicing tape with the intervals between the devices and between the adhesive films stuck to the dicing tape increased by the tape expansion step,
wherein a relative shifting rate between the expansion member and the frame holding means is set to 100 mm/second or more when the expansion member and the dicing tape are brought into abutment against each other in the tape expansion step, and
wherein the increased intervals between the devices and between the adhesive films are each set to 100 μm or more.

2. The method for picking up a device stuck with a adhesive film, according to claim 1,
wherein the adhesive film is cooled to 10° C. or lower in the tape expansion step.
